(19) United States
(12) Patent Application Publication
(10) Pub. No.: US 2009/0162793 A1
(43) Pub. Date: Jun. 25, 2009

(54) Method of Manufacturing Metal Interconnection of Semiconductor Device

(76) Inventor: Kwang Seon CHOI, Yongin-si (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/336,486

(22) Filed: Dec. 16, 2008

(30) Foreign Application Priority Data
Dec. 22, 2007 (KR) 10-2007-0135955

(51) Int. Cl. G03F 7/20

(52) U.S. Cl. 430/317

(57) ABSTRACT

Provided is a method of manufacturing a metal interconnection of a semiconductor device. According to the method, a first dielectric is formed on a semiconductor substrate having a device thereon, and a second dielectric and a metal layer pattern are formed on the first dielectric. Then, a first polymer pattern surrounding a photoresist pattern is formed on the second dielectric, and a via hole is formed in the second dielectric by etching using the first polymer pattern as a mask. The photoresist pattern and the polymer pattern are removed, and a contact is formed by filling the via hole.

### CROSS-REFERENCE TO RELATED APPLICATIONS

The present application claims the benefit under 35 U.S.C. § 119 of Korean Patent Application No. 10-2007-0135955, filed Dec. 22, 2007, which is hereby incorporated by reference in its entirety.

### BACKGROUND

A metal interconnection serves for mutual connections, power supply, and signal transmissions between transistors in an integrated circuit (IC).

Due to the diminution of a design rule as a semiconductor device is highly integrated recently, an aspect ratio, where the width of metal interconnection becomes narrower and its depth becomes deeper, is increased.

One of requirements for developing the semiconductor device is to minimize defects during formation of each metal interconnection layer.

### SUMMARY

Embodiments of the present invention provide a method of manufacturing a metal interconnection of a semiconductor device.

In one embodiment, a method of manufacturing a metal interconnection of a semiconductor device comprises forming a first dielectric on a semiconductor substrate having a device thereon; forming a second dielectric and a metal layer pattern on the first dielectric; forming a first polymer pattern on the second dielectric surrounding a photoresist pattern; forming a via hole on the semiconductor substrate by performing an etching process using the first polymer pattern as a mask; removing the photoresist pattern and the second polymer pattern after forming the via hole; and forming a contact by filling the via hole.

The details of one or more embodiments are set forth in the accompanying drawings and the description below. Other features will be apparent from the description and drawings, and from the claims.

### BRIEF DESCRIPTION OF THE DRAWINGS

FIGS. 1 to 8 are cross-sectional views illustrating an exemplary method of manufacturing a metal interconnection according to embodiments of the invention.

### DETAILED DESCRIPTION OF THE EMBODIMENTS

Hereinafter, a method of manufacturing a metal interconnection according to embodiments of the invention will be described in detail with reference to the accompanying drawings.

It will also be understood that when a layer (or film) is referred to as being ‘on’ another layer or substrate, it can be directly on the other layer or substrate, or intervening layers may also be present.

In the Figures, the thickness or dimension of layers and regions may be for clarity of illustration. In addition, the sizes of the elements and the relative sizes between elements may be exaggerated for further understanding of the present invention.

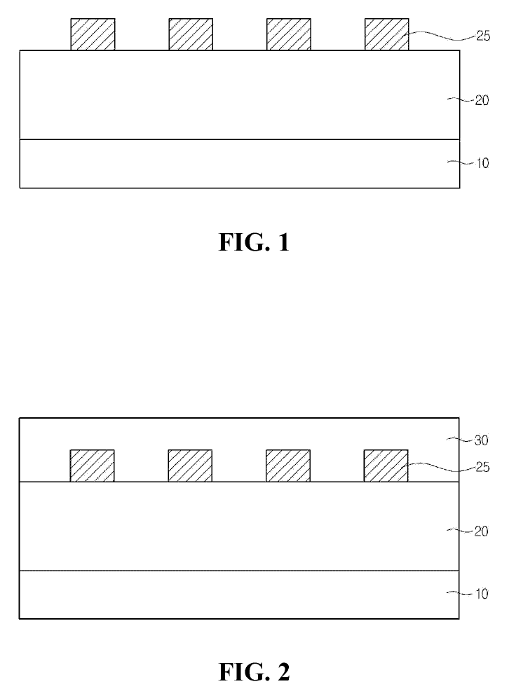

FIGS. 1 to 8 are cross-sectional views illustrating an exemplary method of manufacturing a metal interconnection according to embodiments of the invention.

As illustrated in FIG. 1, an interlayer dielectric 20 is formed on a semiconductor substrate 10 having one or more devices formed thereon, and a metal layer pattern 25 is formed on the interlayer dielectric 20. A device such as a transistor, diode, capacitor, resistor, etc. may be formed on the semiconductor substrate 10. The dielectric layer may comprise a lowermost, conformal etch stop layer (e.g., silicon nitride), a conformal buffer and/or gap-fill layer (e.g., silicon-rich oxide [SRO], TEOS [e.g., a silicon oxide formed by CVD from tetraethyl orthosilicate and oxygen], an undoped silicate glass [USG] or a combination thereof), and a bulk dielectric layer (e.g., one or more silicon oxide layers doped with boron and/or phosphorous [BSG, PSG and/or BPSG]). Alternatively, the bulk dielectric layer may comprise a low-k dielectric, such as a fluorosilicate glass (FSG), silicon oxycarbide (SiOC) or hydrogenated silicon oxycarbide (SiOCH), any of which may comprise upper and lower low-k dielectric layers above and below an intermediate etch stop layer (e.g., silicon nitride). The dielectric layer may further comprise a capping layer, e.g., of TEOS, USG, a plasma silane (e.g., silicon dioxide formed by plasma-assisted CVD of silicon dioxide from silane and oxygen), or a combination thereof, such as a bilayer of plasma silane on USG or TEOS, or a bilayer of USG on TEOS.

The metal layer pattern 25 may be achieved by forming a metal layer on the interlayer dielectric 20 and patterning it.

The metal layer pattern 25 may comprise aluminum (Al).

The metal layer may comprise aluminum or an aluminum alloy (e.g., Al with up to 4 wt. % Cu, up to 2 wt. % Ti, and/or up to 1 wt. % Si), deposited by sputtering on a conventional adhesion and/or barrier layers (e.g., Ti and/or TiN, such as a TiN-on-Ti bilayer), and/or covered by conventional adhesion, barrier, hillock suppression, and/or antireflective layers (e.g., Ti, TiN, WN, TiW alloy, or a combination thereof, such as a TiN-on-Ti bilayer or a TiW-on-Ti bilayer), which may be formed by sputtering or chemical vapor deposition (CVD).

As illustrated in FIG. 2, a second dielectric layer 30 is formed on the metal layer pattern 25. The second dielectric layer 30 may comprise the same layers and/or materials as dielectric layer 20.

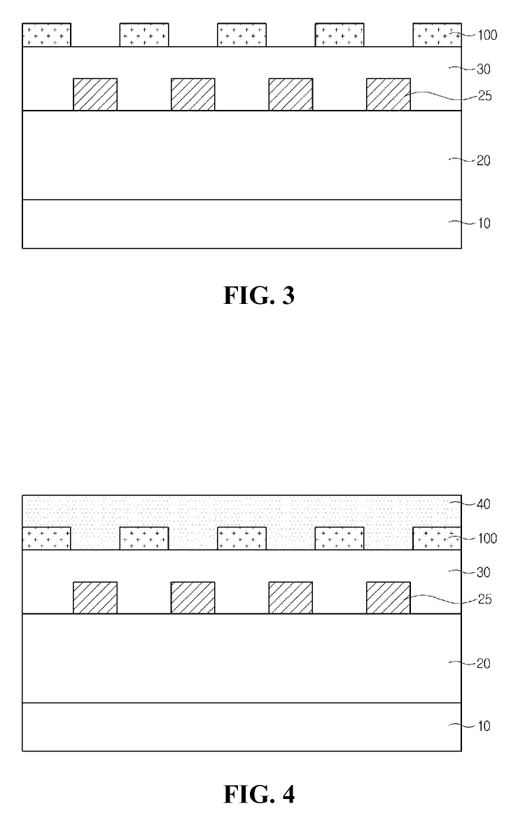

Next, as illustrated in FIG. 3, a photoresist pattern 100 is formed on the dielectric 30.

The photoresist pattern 100 may comprise a resist for krypton fluoride (KrF) lithography and may correspond to a region between the metal layer patterns 25. However, generally, the photoresist pattern 100 defines a plurality of via holes, each exposing a portion of the metal layer 25.

As illustrated in FIG. 4, a first polymer layer 40 is formed on the dielectric 30 and the photoresist pattern 100. The first polymer layer 40 covers the photoresist pattern 100 and may be formed through spin coating. The first polymer layer 40 surrounds the top and side (e.g., sidewalls) of the photoresist pattern 100.

The first polymer layer 40 may comprise a thermosetting material. For example, the first polymer layer 40 may be formed of polyurethane (PU), a phenol resin, a melamine resin or an alkyd resin, but is not limited thereto. Certain epoxy resins that can be removed in accordance with the procedures described herein may also be suitable.

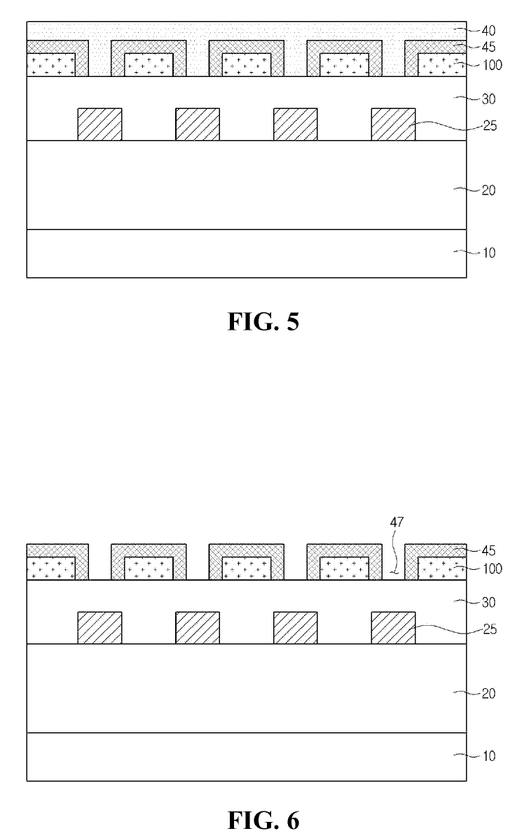

As illustrated in FIG. 5, a second polymer layer 45 is formed between the photoresist pattern 100 and the first polymer layer 40 to form a second polymer pattern 45.

The second polymer pattern 45 may be achieved by forming the second polymer layer between the photoresist pattern 100 and the first polymer layer 40 through a thermal treatment process on the semiconductor substrate 10 including the photoresist pattern 100 and the first polymer layer 40. The thermal treatment process may be performed through a baking process at a temperature of 90° C. to 300° C. Due to the reaction of the photoresist pattern 100 and the first polymer layer 40 during the thermal treatment process, the second polymer layer is formed.

As illustrated in FIG. 6, the first polymer layer 40 on the second polymer pattern 45 is removed. The first polymer layer 40 on the second polymer pattern 45 can be removed through a developing process.

While the first polymer layer 40 is removed through the developing process, the second polymer pattern 45 is not removed. The photoresist pattern 100 and the second polymer pattern 45 remain on the semiconductor substrate 10 where the first polymer layer 40 is removed. At this point, the second polymer pattern 45 surrounds the photoresist pattern 100.

Additionally, an interval between the second polymer patterns 45 is less than that between the photoresist patterns 100. That is, the size of a hole between the photoresist patterns 100 is decreased by the thickness of the second polymer pattern 45 surrounding the photoresist pattern 100.

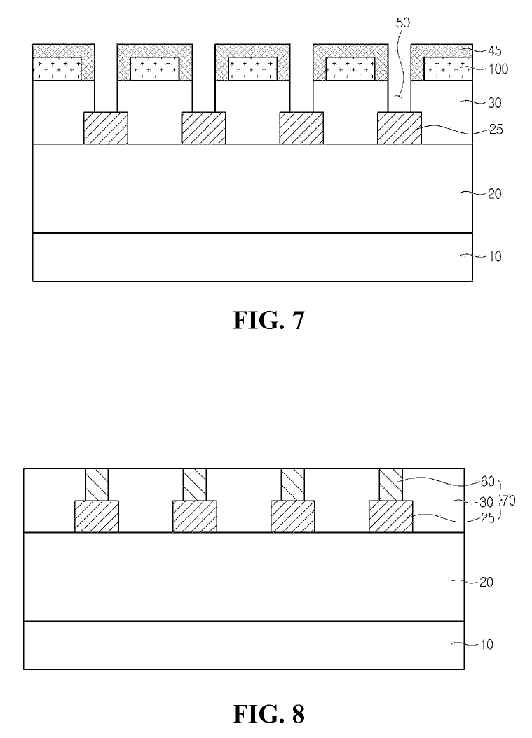

As illustrated in FIG. 7, using the second polymer pattern 45 as a mask, an etching process is performed on the semiconductor substrate 10 (and more specifically, the second dielectric layer 30) to form a via hole 50 exposing the metal layer pattern 25.

Since the width of the hole between the second polymer patterns 45 is less than the interval between the photoresist patterns 100, the width of the via hole 50 formed by the etching process is less than the interval between the photoresist patterns.

That is, during the formation of the photoresist pattern 100 (e.g., a resist for krypton fluoride (KrF) lithography), a sufficient margin can be obtained. The size of a contact that will be formed later can be relatively small by forming the second polymer layer that surrounds the photoresist pattern 100 to narrow the interval between the photoresist patterns 100.

A metal interconnection layer 70 in the dielectric 30, including the metal layer pattern 25 and a contact 60, is obtained by removing the photoresist pattern 100 and the second polymer pattern 45 and filling the via hole 50 to form the contact 60. The contact 60 can be formed by filling the via hole 50 in the dielectric 30 with tungsten (W) and performing a planarization process. The tungsten may be deposited by CVD, and be formed on conventional adhesion and/or barrier layers (e.g., Ti, TiN, and/or TiW, such as a TiN-on-Ti bilayer). The Ti, TiN and TiW layers may be deposited by CVD or sputtering.

According to the above-mentioned method of manufacturing a metal interconnection of a semiconductor device, the size of a contact that will be formed can be less than the interval or hole in the photoresist pattern by forming a second polymer layer to surround the photoresist pattern.

Additionally, during formation of a photoresist pattern, a sufficient margin can be obtained. Therefore, a yield of semiconductor devices can be increased.

Moreover, since a photoresist pattern is formed using related art krypton fluoride (KrF) lithography equipment, no additional equipment is required to obtain a smaller size of a hole.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a metal interconnection of a semiconductor device, the method comprising:
forming a first dielectric on a semiconductor substrate having a device thereon;
forming a second dielectric and a metal layer pattern on the first dielectric;
forming a first polymer pattern on the second dielectric surrounding a photoresist pattern;
forming a via hole by etching using the first polymer pattern as a mask;
removing the photoresist pattern and the first polymer pattern after forming the via hole; and
forming a contact by filling the via hole.

2. The method according to claim 1, wherein forming the first polymer pattern comprises:
forming a photoresist pattern on the second dielectric;
forming a second polymer layer on the photoresist pattern;
forming the first polymer pattern by forming a first polymer layer between the photoresist pattern and the second polymer layer; and
removing the second polymer layer on the first polymer pattern.

3. The method according to claim 2, wherein the first polymer pattern is formed by performing a thermal treatment process on the semiconductor substrate having the photoresist pattern and the second polymer layer thereon.

4. The method according to claim 3, wherein the thermal treatment process is performed at a temperature of 90° C. to 300° C.

5. The method according to claim 2, wherein the second polymer layer is removed by a developing process.

6. The method according to claim 1, wherein the second polymer layer comprises a thermosetting material.

7. The method according to claim 1, wherein the metal layer pattern is exposed when the via hole is formed.

8. The method according to claim 1, wherein the first polymer pattern surrounds a top and side of the photoresist pattern.

9. The method according to claim 1, wherein the first polymer patterns are spaced apart from each other.

10. The method according to claim 1, wherein the photoresist pattern is formed on a corresponding region between the metal layer patterns.

11. A method of manufacturing a metal interconnection of a semiconductor device, the method comprising:
forming a first dielectric layer on a semiconductor substrate having a device thereon;
forming a metal layer pattern on the first dielectric;
forming a second dielectric layer on the metal layer pattern;
forming a photoresist pattern on the second dielectric, the photoresist pattern defining a plurality of via holes;
forming a first polymer pattern surrounding the photoresist pattern;
forming the plurality of via holes by etching the second dielectric using the first polymer pattern and the photoresist pattern as a mask;
after forming the via holes, removing the photoresist pattern and the first polymer pattern; and
forming a contact by filling the via hole with a conductor.

12. The method according to claim 11, wherein forming the first polymer pattern comprises:
forming a second polymer layer on the photoresist pattern;
forming the first polymer pattern at an interface between the photoresist pattern and the second polymer layer by heating the photoresist pattern and the second polymer layer; and
removing the remaining second polymer layer.

13. The method according to claim 12, wherein the photoresist pattern and the second polymer layer are heated at a temperature of 90° C. to 300° C.

14. The method according to claim 12, wherein removing the remaining second polymer layer comprises developing the second polymer layer.

15. The method according to claim 12, wherein the second polymer layer comprises a thermosetting material.

16. The method according to claim 11, wherein forming the via hole exposes the metal layer pattern.

17. The method according to claim 11, wherein the first polymer pattern surrounds a top and sidewalls of the photoresist pattern.
